(19) United States
(12) Patent Application Publication
(10) Pub. No.: US 2026/0079180 A1
(43) Pub. Date: Mar. 19, 2026

(54) PROBE

(71) Applicant: YOKOWO CO., LTD., Tokyo (JP)

(72) Inventor: Kenichi SATO, Tomioka-shi, Gunma (JP)

(73) Assignee: YOKOWO CO., LTD., Tokyo (JP)

(21) Appl. No.: 19/108,738

(22) PCT Filed: Aug. 31, 2023
(86) PCT No.: PCT/JP2023/031784

§ 371 Date: Mar. 5, 2025

(30) Foreign Application Priority Data
Sep. 7, 2022 (JP) 2022-141968

(51) Int. Cl. G01R 1/067; C22C 5/04; C22C 30/02

(52) U.S. Cl. CPC G01R 1/06755; C22C 5/04; C22C 30/02; G01R 1/06722

(57) ABSTRACT

A probe including greater than or equal to 40 mass % and less than or equal to 95 mass % of Pt, greater than or equal to 0.5 mass % and less than or equal to 50 mass % of Cu, and greater than or equal to 3 mass % and less than or equal to 50 mass % of Ni.

### TECHNICAL FIELD

The present invention relates to a probe.

### BACKGROUND ART

To inspect an inspection object such as an integrated circuit, the inspection object is electrically connected to an inspection substrate via a probe provided in a socket. The probe may contain an alloy of Ag, Pd, and Cu. Hereinafter, an alloy of Ag, Pd, and Cu is referred to as a AgPdCu alloy as necessary.

Patent Document 1 describes an example of an alloy of AgPdCu. The AgPdCu alloy described in Patent Document 1 contains greater than or equal to 4% of Ag, about 35% to about 59% of Pd, and greater than or equal to 16% and less than or equal to 50% of Cu.

### RELATED DOCUMENT

### Patent Document

Patent Document 1: U.S. Pat. No. 1,935,897

### SUMMARY OF THE INVENTION

### Technical Problem

The AgPdCu alloy may be used as a material constituting a probe. When the distal end of the probe containing a AgPdCu alloy is repeatedly brought into contact with and electrically connected with a solder as an inspection object, however, there is a tendency that components such as Sn contained in the solder and components contained in the probe are diffused into each other due to factors such as Joule heat. The diffusion of the components contained in the solder may cause the distal end of the probe to be worn. The use of the probe containing the AgPdCu alloy may therefore result in a relatively large number of times of cleaning or replacing the distal end of the probe to reduce an operation rate of an inspection step.

An example of an object of the present invention is to suppress diffusion of a component contained in a solder into a probe. Other objects of the present invention will become apparent from the description of the present specification.

### Solution to Problem

An aspect of the present invention is a probe including:
greater than or equal to 40 mass % and less than or equal to 95 mass % of Pt;
greater than or equal to 0.5 mass % and less than or equal to 50 mass % of Cu; and
greater than or equal to 3 mass % and less than or equal to 50 mass % of Ni.

According to the above-described aspect of the present invention, the diffusion of the component contained in the solder into the probe can be suppressed.

### BRIEF DESCRIPTION OF THE DRAWINGS

FIG. 1 A cross-sectional view showing a socket according to an embodiment.

FIG. 2 A cross-sectional view showing a socket according to a first variant.

FIG. 3 A cross-sectional view showing a probe according to a second variant.

FIG. 4 A triangular graph showing a relationship between a mass ratio of Pt, a mass ratio of Cu, and a mass ratio of Ni contained in test materials according to Examples 1 to 14.

FIG. 5 A scanning electron microscope (SEM) image showing a distal end of a contact portion of a first test pin before an energization durability test.

FIG. 6 An SEM image showing the distal end of the contact portion of the first test pin after the energization durability test.

FIG. 7 An enlarged SEM image showing a distal end of one point of the contact portion of the first test pin after the energization durability test.

FIG. 8 An SEM image showing a distal end of a contact portion of a second test pin before an energization durability test.

FIG. 9 An SEM image showing the distal end of the contact portion of the second test pin after the energization durability test.

FIG. 10 An enlarged SEM image showing the distal end of one point of the contact portion of the second test pin after the energization durability test.

FIG. 11 An SEM image showing a distal end of a contact portion of a third test pin before an energization durability test.

FIG. 12 An SEM image showing the distal end of the contact portion of the third test pin after the energization durability test.

FIG. 13 An enlarged SEM image showing a distal end of one point of the contact portion of the third test pin after the energization durability test.

FIG. 14 An SEM image showing a distal end of a contact portion of a fourth test pin before an energization durability test.

FIG. 15 An SEM image showing the distal end of the contact portion of the fourth test pin after the energization durability test.

FIG. 16 An enlarged SEM image showing a distal end of one point of the contact portion of the fourth test pin after the energization durability test.

### DESCRIPTION OF EMBODIMENTS

Hereinafter, embodiments and variants of the present invention will be described with reference to the accompanying drawings. In all drawings, the same constituent elements are denoted by the same reference signs, and detailed description thereof will not be repeated.

In the present specification, ordinal numbers such as “first”, “second”, and “third” are attached only for distinguishing components to which the same names are attached unless otherwise specified, and do not mean particular features (for example, an order or a degree of importance) of the components.

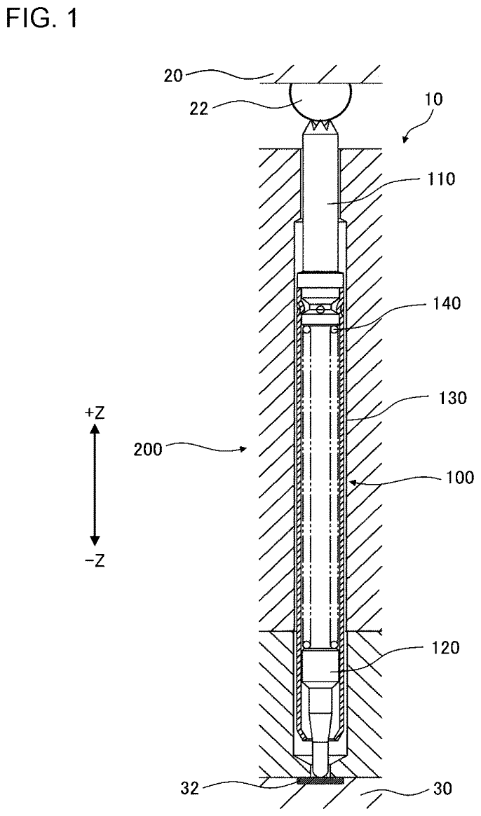

FIG. 1 is a cross-sectional view showing a socket 10 according to an embodiment.

In FIG. 1, the arrow indicated by “+Z” indicates an upward direction in the vertical direction, and the arrow indicated by “−Z” indicates a downward direction in the vertical direction. Hereinafter, as necessary, a direction orthogonal to the vertical direction will be referred to as a horizontal direction.

The socket 10 includes a probe 100 and an insulating support 200. The probe 100 is provided in a through-hole formed in the insulating support 200. The probe 100 includes a first plunger 110, a second plunger 120, a tube 130, and a spring 140. FIG. 1 shows that an inspection object 20 is inspected by an inspection substrate 30 using the probe 100. Specifically, the state shown in FIG. 1 is a state in which a solder ball 22 of the inspection object 20 and a pad 32 of the inspection substrate 30 are electrically connected to each other via the probe 100.

The tube 130 extends in the vertical direction. The spring 140 is positioned inside the tube 130. The probe 100 may include no tube 130. The spring 140 is spirally wound around a virtual axis passing through the center of the tube 130 in the vertical direction.

The first plunger 110 is positioned on the upper end side of the spring 140. The first plunger 110 is biased upward by the spring 140, that is, in a direction away from the second plunger 120. While the inspection object 20 is inspected by the inspection substrate 30, the first plunger 110 is connected to the inspection object 20 positioned above the probe 100. While the inspection object 20 is inspected by the inspection substrate 30, the distal end, that is, the upper end of the first plunger 110 is in contact with the solder ball 22 of the inspection object 20. In the example shown in FIG. 1, the distal end of the first plunger 110 has a plurality of points arranged at equal intervals around a virtual axis passing through the center of the first plunger 110 in the vertical direction. The shape of the distal end of the first plunger 110 is not limited to the example shown in FIG. 1.

The second plunger 120 is positioned on the lower end side of the spring 140. The second plunger 120 is biased downward by the spring 140, that is, in a direction away from the first plunger 110. While the inspection object 20 is inspected by the inspection substrate 30, the second plunger 120 is connected to the inspection substrate 30 positioned below the probe 100. While the inspection object 20 is inspected by the inspection substrate 30, the distal end, that is, the lower end of the second plunger 120 is in contact with the pad 32 of the inspection substrate 30. The distal end of the second plunger 120 has a hemispherical shape. The shape of the distal end of the second plunger 120 is not limited to the example shown in FIG. 1.

The first plunger 110 contains a material (A). The material (A) contains greater than or equal to 40 mass % and less than or equal to 95 mass % of Pt, greater than or equal to 0.5 mass % and less than or equal to 50 mass % of Cu, and greater than or equal to 3 mass % and less than or equal to 50 mass % of Ni. For example, at least a surface of the first plunger 110 is made of the material (A). In the example in which at least the surface of the first plunger 110 is made of the material (A), for example, the entire first plunger 110 may be formed of the material (A). Alternatively, the material (A) may cover the surface of the first plunger 110 by a treatment such as plating. When the material (A) covers the surface of the first plunger 110, a portion of the first plunger 110 covered with the material (A) may be formed of a material different from the material (A). At least a portion of the first plunger 110 in contact with the solder ball 22, for example, may be made of the material (A). In an example in which at least a portion of the first plunger 110 in contact with the solder ball 22 is made of the material (A), for example, the material (A) may cover only the surface of the portion of the first plunger 110 in contact with the solder ball 22 by a treatment such as plating.

The lower limit of the mass ratio of Pt contained in the material (A) is determined from the viewpoint of the corrosion resistance of the material (A). When the mass ratio of Pt contained in the material (A) is less than 40 mass %, the corrosion resistance of the material (A) may be insufficient, and thus the mass ratio of Pt contained in the material (A) can be greater than or equal to 40 mass %. The mass ratio of Pt contained in the material (A) may be greater than or equal to 45 mass % or greater than or equal to 50 mass %.

The upper limit of the mass ratio of Pt contained in the material (A) is determined from the viewpoint of the hardness of the material (A) work-hardened by high deformation. When the mass ratio of Pt contained in the material (A) is greater than 95 mass %, the hardness of the material (A) work-hardened by high deformation may not reach 300 HV and may not reach the hardness required for the first plunger 110; therefore, the mass ratio of Pt contained in the material (A) can be less than or equal to 95 mass %. The mass ratio of Pt contained in the material (A) may be less than or equal to 90 mass % or less than or equal to 83 mass %.

The mass ratio of Pt contained in the material (A) can be, for example, greater than or equal to 45 mass % and less than or equal to 90 mass %. Alternatively, the mass ratio of Pt contained in the material (A) can be, for example, greater than or equal to 50 mass % and less than or equal to 83 mass %.

The lower limit of the mass ratio of Cu contained in the material (A) is determined from the viewpoint of the hardness of the material (A). The addition of Cu to Pt can be improvement of the hardness of the material (A) while satisfactorily maintaining the workability of the material (A). When the mass ratio of Cu contained in the material (A) is less than 0.5 mass %, however, the hardness of the material (A) may be insufficient; therefore, the mass ratio of Cu contained in the material (A) can be greater than or equal to 0.5 mass %. The mass ratio of Cu contained in the material (A) may be greater than or equal to 2 mass % or greater than or equal to 5 mass %. The mass ratio of Cu contained in the material (A) may be greater than or equal to 9 mass %.

The upper limit of the mass ratio of Cu contained in the material (A) is determined from the viewpoint of the corrosion resistance of the material (A). When the mass ratio of Cu contained in the material (A) is greater than 50 mass %, the corrosion resistance of the material (A) may be insufficient; therefore, the mass ratio of Cu contained in the material (A) can be less than or equal to 50 mass %. The mass ratio of Cu contained in the material (A) may be less than or equal to 40 mass % or less than or equal to 30 mass %.

The mass ratio of Cu contained in the material (A) can be, for example, greater than or equal to 2 mass % and less than or equal to 40 mass %. Alternatively, the mass ratio of Cu contained in the material (A) can be, for example, greater than or equal to 5 mass % and less than or equal to 30 mass %.

The lower limit of the mass ratio of Ni contained in the material (A) is determined from the viewpoint of the hardness of the work-hardened material (A). When the material (A) contains Ni, the hardness of the work-hardened material (A) can be improved without decreasing suppression of diffusion of the component contained in the material (A) and the component contained in the solder such as the solder ball 22. When the mass ratio of Ni contained in the material (A) is less than 3 mass %, however, the hardness of the work-hardened material (A) may be insufficient; therefore, the mass ratio of Ni contained in the material (A) can be greater than or equal to 3 mass %. The mass ratio of Ni contained in the material (A) may be greater than or equal to 5 mass % or greater than or equal to 10 mass %.

The upper limit of the mass ratio of Ni contained in the material (A) is determined, for example, from the viewpoint of plastic working such as cold rolling and wire drawing of the material (A). When the mass ratio of Ni contained in the material (A) is greater than 50 mass %, plastic working such as cold rolling or wire drawing of the material (A) may be difficult; therefore, the mass ratio of Ni contained in the material (A) can be less than or equal to 50 mass %. The mass ratio of Ni contained in the material (A) may be, for example, less than or equal to 40 mass % or less than or equal to 35 mass %.

The mass ratio of Ni contained in the material (A) can be, for example, greater than or equal to 5 mass % and less than or equal to 40 mass %. Alternatively, the mass ratio of Ni contained in the material (A) can be, for example, greater than or equal to 10 mass % and less than or equal to 35 mass %.

In the embodiment, the diffusion of the component contained in the solder ball 22 into the first plunger 110 at the interface between the distal end of the first plunger 110 and the surface of the solder ball 22 can be suppressed as compared with when the first plunger 110 contains the AgPdCu alloy. In the embodiment, the diffusion of the component contained in the solder ball 22 into the first plunger 110 is suppressed so that the wearing of the distal end of the first plunger 110 can be suppressed as compared with when the first plunger 110 contains the AgPdCu alloy.

The reason why the diffusion of the component contained in the solder into the material (A) is suppressed when the material (A) is used as compared with when the AgPdCu alloy is used is presumed to be as follows. That is, the Ni contained in the material (A) causes a dense thin film containing a metal compound such as Sn—Ni to be formed at the interface between the material (A) and the solder on contacting of the material (A) and the solder. The diffusion of the components contained in the material (A) and the solder is suppressed by the metal compound when the metal compound is present at the interface between the material (A) and the solder as compared with when the metal compound is not present at the interface between the material (A) and the solder. When the AgPdCu alloy is used, however, the above metal compound is difficult to form. In the embodiment, accordingly, the diffusion of the component contained in the solder ball 22 into the first plunger 110 between the distal end of the first plunger 110 and the solder ball 22 can be suppressed as compared with when the first plunger 110 contains the AgPdCu alloy.

The material (A) does not need to be as hard as the existing AgPdCu alloy. As the number of inspections increases, however, the contact surface of the first plunger 110 may be mechanically crushed; therefore, it is desirable for the material (A) to be relatively hard. For example, the first plunger 110 is available with a hardness of greater than or equal to 200 HV. The hardness of the material (A) is required to be greater than or equal to 250 HV and preferably 300 HV. The hardness of the material (A) may be a hardness improved by work hardening.

The material (A) may need to have a relatively low specific resistance. For example, the specific resistance of the material (A) can be less than or equal to 90 μΩ·cm. The low specific resistance of the material (A) can suppress the Joule heat generated from the material (A) in the inspection using the probe 100.

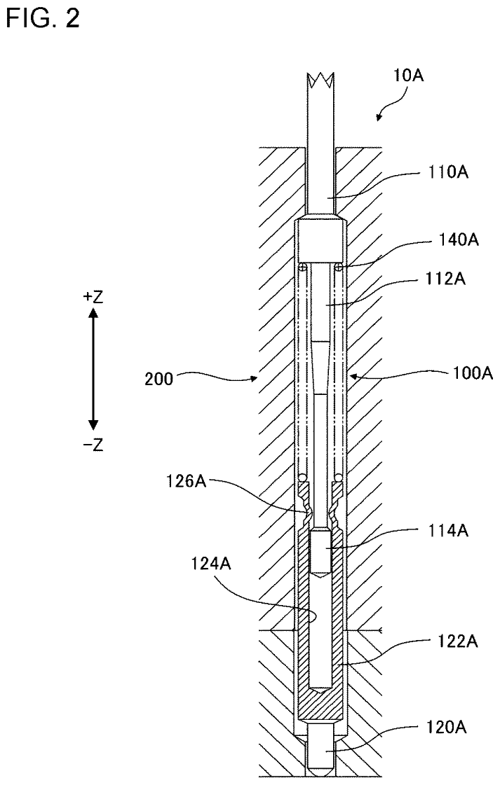

FIG. 2 is a cross-sectional view of a socket 10A according to a first variant. The socket 10A according to the present variant is the same as the probe 100 according to the embodiment except for the following points.

The lower end of the first plunger 110A is provided with an extending portion 112A that extends downward from the first plunger 110A. The first plunger 110A and the extending portion 112A are integrated with each other. Accordingly, both the first plunger 110A and the extending portion 112A contain the material (A). The distal end head 114A is provided on the lower end of the extending portion 112A. The distal end head 114A may or may not contain the material (A).

A proximal end portion 122A is provided on the upper end of the second plunger 120A. A hole 124A upward open from the proximal end portion 122A is formed on the upper surface of the proximal end portion 122A. A locking portion 126A is provided on a portion of the inner wall of the proximal end portion 122A defining the hole 124A. The diameter of the hole 124A at the locking portion 126A in the horizontal direction is less than the diameter of the portion of the hole 124A positioned below the locking portion 126A in the horizontal direction. The distal end head 114A is inserted below the locking portion 126A of the hole 124A. The distal end head 114A is movable in the vertical direction below the locking portion 126A of the hole 124A. The diameter of the distal end head 114A in the horizontal direction is greater than the diameter of the hole 124A at the locking portion 126A in the horizontal direction. Accordingly, the locking portion 126A prevents the distal end head 114A from being removed upwardly through the hole 124A.

The probe 100A according to the present variant does not have a tube corresponding to the tube 130 of the probe 100 according to the embodiment. The spring 140A is positioned between the lower end of the first plunger 110A and the upper end of the proximal end portion 122A. The spring 140A is spirally wound around the extending portion 112A. The first plunger 110A, the extending portion 112A, and the distal end head 114A are biased upward by the spring 140A. The second plunger 120A and the proximal end portion 122A are biased downward by the spring 140A.

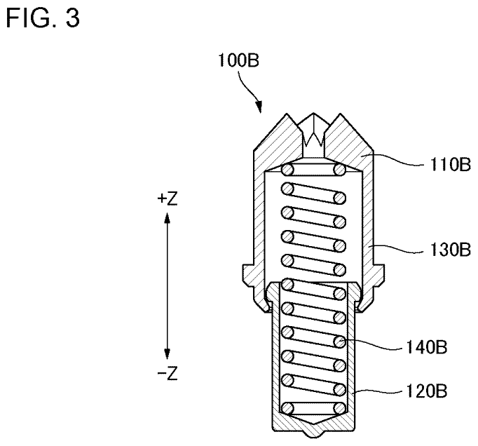

FIG. 3 is a cross-sectional view of a probe 100B according to a second variant. The probe 100B according to the present variant is the same as the probe 100 according to the embodiment except for the following points.

In the example shown in FIG. 3, the first plunger 110B and the tube 130B are integrated with each other. Accordingly, both the first plunger 110B and the tube 130B contain the material (A). The first plunger 110B and the tube 130B are biased upward by the spring 140B, that is, in a direction away from the second plunger 120B. The second plunger 120B is biased downward by the spring 140B, that is, in a direction away from the first plunger 110B.

Although the embodiments and variants of the present invention have been described with reference to the accompanying drawings, these are merely examples of the present invention, and various other configurations may be employed.

### EXAMPLES

One aspect of the present invention will be described based on examples and comparative examples. The present invention is not limited to the following examples.

Table 1 lists the composition contained in each test material of Examples 1 to 14 and Comparative Examples 1 and 2. In Examples 1 to 14 and Comparative Example 2 of Table 1, “αPtβCuγNi” denotes that the test material contains a mass % of Pt, β mass % of Cu, and γ mass % of Ni. In Comparative Example 1, “24.5Ag45Pd25Cu0.5In” denotes that the test material contains 24.5 mass % of Ag, 45 mass % of Pd, 25 mass % of Cu, and 0.5 mass % of In.

TABLE 1

| | Composition |
|---|---|
| Example 1 | 95Pt2Cu3Ni |
| Example 2 | 90Pt0.5Cu9.5Ni |
| Example 3 | 90Pt5Cu5Ni |
| Example 4 | 80Pt15Cu5Ni |
| Example 5 | 80Pt10Cu10Ni |
| Example 6 | 70Pt25Cu5Ni |
| Example 7 | 70Pt10Cu20Ni |
| Example 8 | 60Pt30Cu10Ni |
| Example 9 | 60Pt20Cu20Ni |
| Example 10 | 60Pt10Cu30Ni |
| Example 11 | 50Pt40Cu10Ni |
| Example 12 | 50Pt30Cu20Ni |
| Example 13 | 50Pt10Cu40Ni |
| Example 14 | 40Pt40Cu20Ni |
| Comparative | 24.5Ag45Pd25Cu0.5In |
| Example 1 | |
| Comparative | 37Pt3Cu60Ni |
| Example 2 | |

Each of the test materials of Examples 1 to 14 and Comparative Examples 1 and 2 was produced as follows.

In Example 1, as listed in Table 1, 95 mass % of Pt, 2 mass % of Cu, and 3 mass % of Ni were blended to achieve a blend. In each of Examples 2 to 14 and Comparative Example 2, Pt, Cu, and Ni were blended in accordance with the compositions of Examples 2 to 14 and Comparative Example 2 listed in Table 1 to achieve a blend. In Comparative Example 1, Ag, Pd, Cu, and In were blended in accordance with the composition of Comparative Example 1 listed in Table 1 to achieve a blend.

Next, in each of Examples 1 to 14 and Comparative Examples 1 and 2, the blend was melted by arc melting in an argon atmosphere to produce an alloy ingot.

Next, in each of Examples 1 to 14 and Comparative Examples 1 and 2, rolling and a heat treatment for the alloy ingot were repeatedly performed to produce a plate material having a rolling rate of 80%. A rolling rate RR is determined according to Equation (1):

$$RR = \{ ( t 1 - t 2 ) / t 1 \} \times 100 \qquad ( 1 )$$

where t1 is the thickness of the alloy ingot before rolling and t2 is the thickness of the alloy ingot after rolling.

In Examples 1 to 14 and Comparative Example 1, a plate material having a rolling rate of 80% could be produced. In Comparative Example 2, a plate material having a rolling rate of 80% could not be produced. In Comparative Example 2, the measurement described below with reference to Table 2 was not performed.

Table 2 lists measurement results of the specific resistance (unit: μΩ·cm) of the test material, the hardness (unit: HV) of the worked material of the test material, and the thickness (unit: μm) of the diffusion layer between the test material and the solder for each of Examples 1 to 14 and Comparative Example 1.

TABLE 2

| | | Hardness | Thickness |
|---|---|---|---|
| | Specific | of worked | of diffusion |
| | resistance | material | layer |
| | (μΩ · cm) | (HV) | (μm) |
| Example 1 | 31 | 300 | 30 |
| Example 2 | 32 | 385 | 40 |
| Example 3 | 48 | 360 | 40 |
| Example 4 | 67 | 370 | 40 |
| Example 5 | 58 | 400 | 20 |
| Example 6 | 79 | 360 | 15 |
| Example 7 | 49 | 425 | 20 |
| Example 8 | 60 | 390 | 20 |
| Example 9 | 66 | 435 | 20 |
| Example 10 | 52 | 430 | 25 |
| Example 11 | 60 | 350 | 35 |
| Example 12 | 66 | 425 | 30 |
| Example 13 | 53 | 420 | 35 |
| Example 14 | 58 | 340 | 30 |
| Comparative | 25 | 350 | greater than |
| Example 1 | | | or equal to |
| | | | 600 |

In each of Examples 1 to 20 and Comparative Example 1, the specific resistance of the test material was measured by measuring the electrical resistance R of the test material at room temperature and calculating the specific resistance p according to Equation (2):

$$ρ = RS / 1 \qquad ( 2 )$$

where 1 represents a measurement length of the test material in a direction in which a current flows in the test material, and S represents a cross-sectional area of the test material perpendicular to the direction in which the current flows in the test material. In the measurement of the specific resistance, a plate material having a rolling rate of 90% was used as the test material.

As listed in Table 2, in Examples 1 to 14, the specific resistance was less than 90 μΩ·cm. Accordingly, the specific resistance required for the probe could be achieved in Examples 1 to 14.

In each of Examples 1 to 14 and Comparative Example 1, the hardness of the worked material of the test material was measured by holding the center of the cross section of the test material with a load of 200 gf for 10 seconds with a micro Vickers hardness tester.

As listed in Table 2, in Examples 1 to 14, the hardness of the worked material was greater than or equal to 300 HV. Accordingly, the hardness required for the probe could be achieved in Examples 1 to 14.

In each of Examples 1 to 14 and Comparative Example 1, the thickness of the diffusion layer between the test material and the solder was measured as follows. First, a Sn—Bi-based solder was placed on a test material of 10 mm×10 mm×a thickness of 0.5 mm. Next, while the Sn—Bi-based solder was placed on the test material, the test material and the Si—Bi-based solder were subjected to a heat treatment in a N₂ atmosphere at 250° C. for 1 hour to melt the solder on the test material. Next, the test material was embedded in a resin to expose a cross section including both the test material and the solder. Next, the interface between the test material and the solder was linearly analyzed in a direction perpendicular to the interface using an electron probe micro analyzer (EPMA). In Examples 1 to 14, the diffusion layer was deemed as a layer in which both Sn diffused from the solder and Pt of the main element diffused from the test material were present in the linear analysis. In Comparative Example 1, the diffusion layer was deemed as a layer in which both Sn diffused from the solder and Pd of the main element diffused from the test material were present in the linear analysis.

As listed in Table 2, in Comparative Example 1, the thickness of the diffusion layer was greater than or equal to 600 μm. In Examples 1 to 14, the thickness of the diffusion layer was less than 100 μm. Accordingly, the diffusion of the component contained in the solder into the test material can be suppressed in Examples 1 to 14 as compared with Comparative Example 1.

From the results listed in Table 2, the diffusion of component contained in the solder into the test material could be suppressed while the specific resistance and the hardness of the worked material required for the probe were realized in the test materials according to Examples 1 to 14 as compared with the test material according to Comparative Example 1.

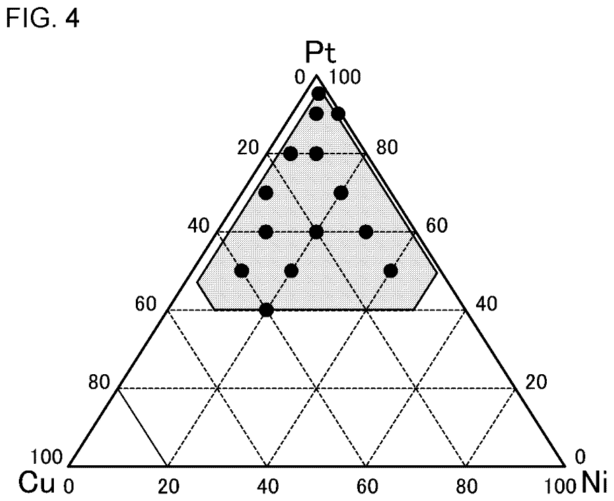

FIG. 4 is a triangular graph showing the relationship between the mass ratio of Pt, the mass ratio of Cu, and the mass ratio of Ni contained in the test materials according to Examples 1 to 14.

The side of the triangular graph from the lower right vertex to the upper center vertex indicates the mass ratio (unit: mass %) of Pt contained in the test material. The side of the triangular graph from the upper center vertex to the lower left vertex indicates the mass ratio (unit: mass %) of Cu contained in the test material. The side of the triangular graph from the lower left vertex to the lower right vertex indicates the mass ratio (unit: mass %) of Ni contained in the test material.

In the triangular graph of FIG. 4, a hatched region indicates a range where the mass ratio of Pt is greater than or equal to 40 mass % and less than or equal to 95 mass %, the mass ratio of Cu is greater than or equal to 0.5 mass % and less than or equal to 50 mass %, and the mass ratio of Ni is greater than or equal to 3 mass % and less than or equal to 50 mass %. The plots of Examples 1 to 14 are positioned in the hatched regions. From the tendency of the plots of Examples 1 to 14, the diffusion of the component contained in the solder into the test material can be suppressed in any of the hatched regions as compared with when the test material is a AgPdCu alloy.

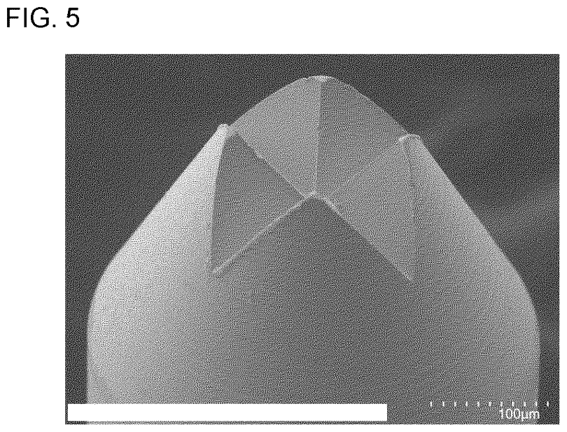

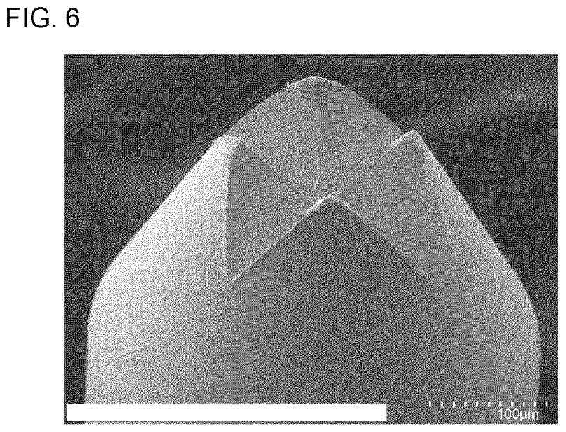

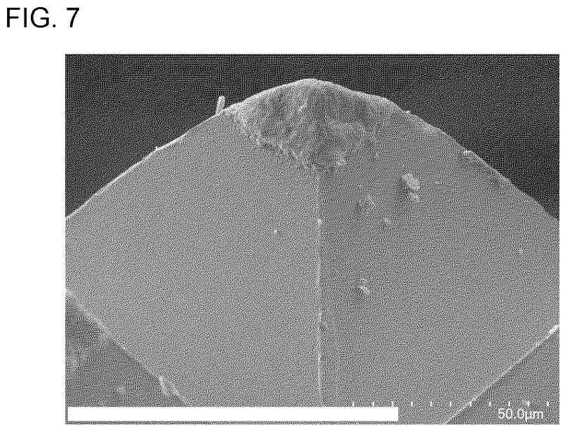

FIG. 5 is a scanning electron microscope (SEM) image showing a distal end of the contact portion of the first test pin before the energization durability test. FIG. 6 is an SEM image showing a distal end of the contact portion of the first test pin after the energization durability test. FIG. 7 is an enlarged SEM image showing a distal end of one point of the contact portion of the first test pin after the energization durability test.

The first test pin includes the test material of Example 2. As shown in FIGS. 5 and 6, the distal end of the contact portion of the first test pin has four points arranged at equal intervals around the central axis of the test pin.

In the energization durability test, using a flying probe tester, the contact of the distal end of the contact portion of the first test pin with Sn-40Bi solder at a temperature of 125° C. and the conduction of a current of 1 A for 20 ms were repeated 10,000 times.

The amount of the first test pin worn was calculated by comparing the length of the first test pin before the energization durability test and the length of the first test pin after the energization durability test. The amount of the first test pin worn was 0 μm.

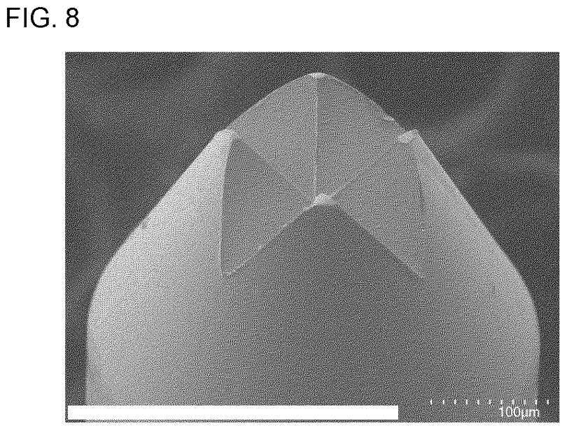

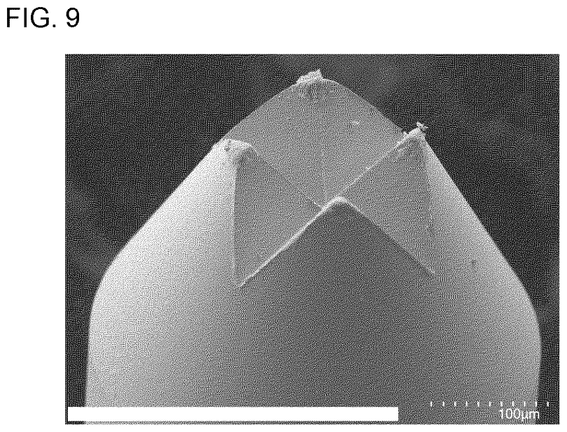

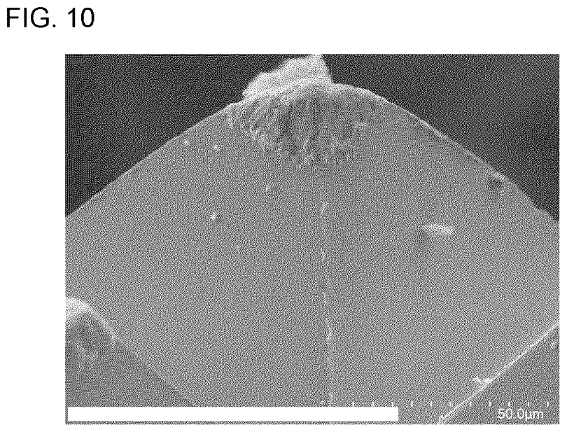

FIG. 8 is an SEM image showing a distal end of the contact portion of the second test pin before the energization durability test. FIG. 9 is an SEM image showing the distal end of the contact portion of the second test pin after the energization durability test. FIG. 10 is an enlarged SEM image showing the distal end of one point of the contact portion of the second test pin after the energization durability test.

The second test pin was the same as the first test pin except that the second test pin contained the test material of Example 3. The conditions of the energization durability test of the second test pin were the same as the conditions of the energization durability test of the first test pin.

The amount of the first test pin worn was calculated by comparing the length of the second test pin before the energization durability test and the length of the second test pin after the energization durability test. The amount of the second test pin worn was 0 μm.

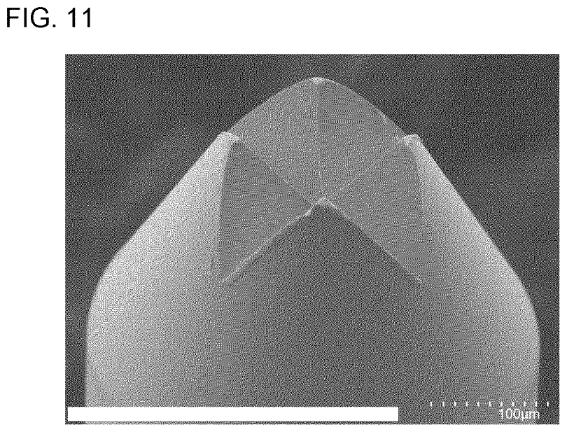

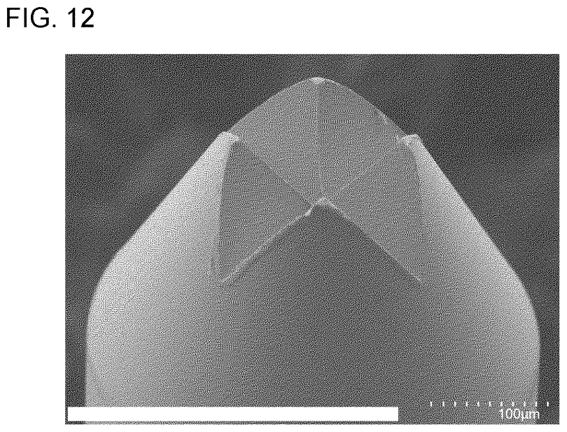

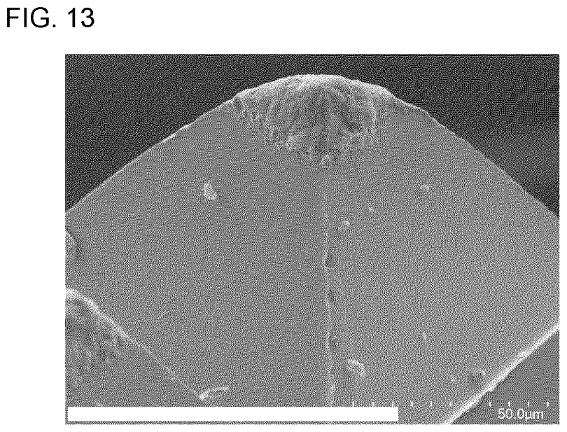

FIG. 11 is an SEM image showing a distal end of the contact portion of the third test pin before the energization durability test. FIG. 12 is an SEM image showing a distal end of the contact portion of the third test pin after the energization durability test. FIG. 13 is an enlarged SEM image showing the distal end of one point of the contact portion of the third test pin after the energization durability test.

The third test pin was the same as the first test pin except that the third test pin contained the test material of Example 8. The conditions of the energization durability test of the third test pin were the same as the conditions of the energization durability test of the first test pin.

The amount of the first test pin worn was calculated by comparing the length of the third test pin before the energization durability test and the length of the third test pin after the energization durability test. The amount of the third test pin worn was 1 μm.

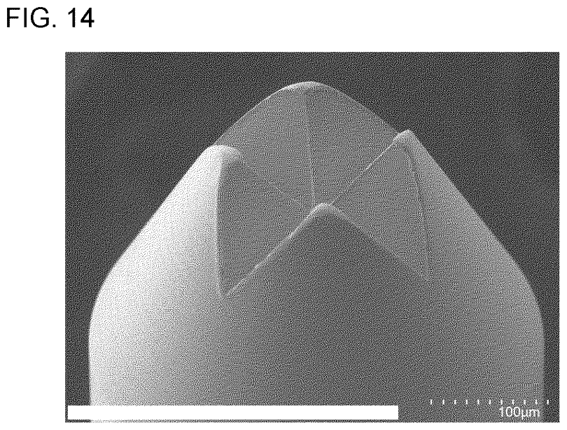

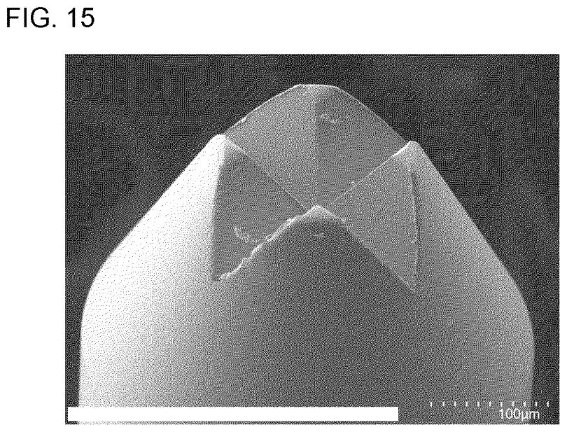

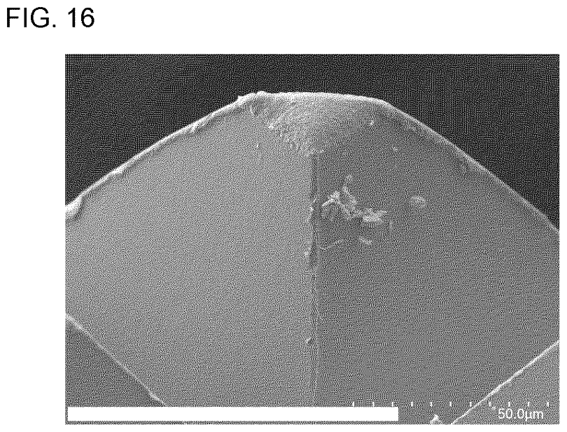

FIG. 14 is an SEM image showing a distal end of the contact portion of the fourth test pin before the energization durability test. FIG. 15 is an SEM image showing a distal end of the contact portion of the fourth test pin after the energization durability test. FIG. 16 is an enlarged SEM image showing a distal end of one point of the contact portion of the fourth test pin after the energization durability test.

The fourth test pin was the same as the first test pin except that the fourth test pin contained the test material of Comparative Example 1. The conditions of the energization durability test of the fourth test pin were the same as the conditions of the energization durability test of the first test pin.

The amount of the first test pin worn was calculated by comparing the length of the fourth test pin before the energization durability test and the length of the fourth test pin after the energization durability test. The amount of the fourth test pin worn was 4 μm.

From the results of the amounts of the first test pin, the second test pin, the third test pin, and the fourth test pin worn, the wear of the distal end of the test pin could be suppressed when the test pin contains greater than or equal to 40 mass % and less than or equal to 95 mass % of Pt, greater than or equal to 0.5 mass % and less than or equal to 50 mass % of Cu, and greater than or equal to 3 mass % and less than or equal to 50 mass % of Ni as compared with when the test pin contains a AgPdCu alloy.

According to the present specification, a probe of the following aspect is provided.

### (Aspect 1)

In the aspect 1, a probe contains greater than or equal to 40 mass % and less than or equal to 95 mass % of Pt, greater than or equal to 0.5 mass % and less than or equal to 50 mass % of Cu, and greater than or equal to 3 mass % and less than or equal to 50 mass % of Ni.

According to the above aspect, the diffusion of the component contained in the solder into the probe at the interface between the probe and the solder can be suppressed as compared with the AgPdCu alloy.

This application claims priority based on Japanese Patent Application No. 2022-141968, filed Sep. 7, 2022, the disclosure of which is incorporated herein by reference.

### REFERENCE SIGNS LIST

10, 10A socket, 20 inspection object, 22 ball, 30 inspection substrate, 32 pad, 100, 100A, 100B probe, 110, 110A, 110B first plunger, 112A extending portion, 114A distal end head, 120, 120A, 120B second plunger, 122A proximal end portion, 124A hole, 126A locking portion, 130, 130B tube, 140, 140A, 140B spring, 200 insulating support

1. A probe comprising:
greater than or equal to 40 mass % and less than or equal to 95 mass % of Pt;
greater than or equal to 0.5 mass % and less than or equal to 50 mass % of Cu; and
greater than or equal to 3 mass % and less than or equal to 50 mass % of Ni.
